(19) United States
(12) Patent Application Publication
(10) Pub. No.: US 2026/0271637 A1
(43) Pub. Date: Sep. 10, 2026

(54) PRECURSOR FOR FORMING LOW DIELECTRIC CONSTANT SILICON-CONTAINING THIN FILM AND METHOD FOR FORMING LOW DIELECTRIC CONSTANT SILICON-CONTAINING THIN FILM USING SAME

(71) Applicants: SK TRI CHEM CO., LTD., Sejong (KR); SK HYNIX INC., Icheon-si (KR)

(72) Inventors: Jong Ryul PARK, Sejong (KR); Seok Hee SHIN, Sejong (KR); Yong Joo PARK, Sejong (KR); Tae Hyeong KANG, Sejong (KR); Sang Kyung LEE, Sejong (KR); So Yeong PARK, Icheon-si (KR); Dong Kyun LEE, Icheon-si (KR); Sang Hyun LEE, Icheon-si (KR); Tae Hwan LIM, Icheon-si (KR)

(21) Appl. No.: 19/491,304

(22) PCT Filed: Jun. 4, 2024
(86) PCT No.: PCT/KR2024/007656

§ 371 Date: Dec. 8, 2025

(30) Foreign Application Priority Data
Jun. 8, 2023 (KR) 10-2023-0073662

(51) Int. Cl. H10P 14/60; H10P 14/692

(52) U.S. Cl. CPC H10P 14/6686; H10P 14/6336; H10P 14/6924; H10P 14/6339; H10P 14/6342

(57) ABSTRACT

The present invention relates to: a precursor for forming a low dielectric constant silicon-containing thin film, the precursor containing a silicon-containing compound represented by chemical formula 1 or chemical formula 2; and a method for forming a thin film using the precursor. The precursor for forming a low dielectric constant silicon-containing thin film forms a low dielectric constant silicon-containing thin film having a dielectric constant of 2.2-3.6. The precursor is a liquid at room temperature and thus easy to store and handle, and has high reactivity and thus can easily form a high-quality silicon-containing thin film at an excellent growth rate.

### TECHNICAL FIELD

The present disclosure relates to a precursor for forming a silicon-containing thin film and a method for forming a silicon-containing thin film using the same, and more particularly, to a precursor that comprises a silicon-containing compound having a cyclic disilane structure, is a liquid at room temperature and thus easy to store and handle, and has high reactivity, thereby enabling the formation of a high-quality low dielectric constant silicon-containing thin film at an excellent growth rate, and a method for forming a silicon-containing thin film using the same.

### BACKGROUND ART

As semiconductor devices become smaller and more highly integrated, parasitic capacitance increases, leading to a delay in response speed (RC delay). To address this issue, research and development have been conducted. The parasitic capacitance mainly occurs as the spacing between metal wirings becomes very small, resulting in the arrangement of the metal wirings having the same structure as a capacitor. To reduce the parasitic capacitance, it is necessary to form an interlayer insulating film formed between the metal wirings as an insulating material having a low dielectric constant.

The insulating material having a low dielectric constant may be formed by a spin-on dielectric (SOD) method or a chemical vapor deposition (CVD) method. Examples thereof include a fluorine-containing silicon oxide film (fluorinated silicate glass, hereinafter a FSG film) and a SiOC film.

Conventionally used precursors for forming low dielectric constant thin films include octamethylcyclotetrasiloxane (OMCTS), diethoxymethylsilane (DEMS), and tetraethoxyorthosilicate (TEOS). Although these precursors are a liquid and thus advantageous for vaporization during the deposition process, it is difficult to obtain a sufficient elastic modulus in the formed thin film, which limits their range of applications.

For example, Korean Laid-Open Patent Publication No. 10-2006-0029762 discloses a process for forming an insulating film using SiH₄ and SiF₄ gases, in which organic siloxane source gases such as MTES, DEMS, DMOMS, TOMCATS, DMDMOS, DMDOSH, and Z3MS are used; however, such organic siloxane sources are only added as supplementary components to the precursor and thus have limitations in lowering the dielectric constant. Furthermore, when the organic siloxane source is used as a precursor, a problem arises in that the resulting film has a low elastic modulus, thereby limiting its use in a thin film formation process.

### DISCLOSURE

### Technical Problem

The present disclosure has been devised in consideration of the above-described prior arts, and its purpose is to provide a precursor for forming a low dielectric constant silicon-containing thin film, which comprises a silicon-containing compound having a cyclic disilane structure, is a liquid at room temperature and thus easy to store and handle, and has high reactivity, thereby enabling an excellent thin film growth rate.

Another purpose of the present disclosure is to provide a precursor for forming a low dielectric constant silicon-containing thin film that is capable of easily controlling a carbon content ratio within a molecule and improving an elastic modulus of the formed thin film.

Still another purpose of the present disclosure is to provide a method capable of forming a low dielectric constant silicon-containing thin film having a high elastic modulus by using the precursor for forming a low dielectric constant silicon-containing thin film described above.

### Technical Solution

In order to achieve the above objects, the precursor for forming a low dielectric constant silicon-containing thin film according to the present disclosure, comprises a silicon-containing compound represented by the following Chemical Formula 1 or Chemical Formula 2, and is characterized in that the silicon-containing thin film formed using the precursor for forming a low dielectric constant silicon-containing thin film has a low dielectric constant of 2.2 to 3.6.

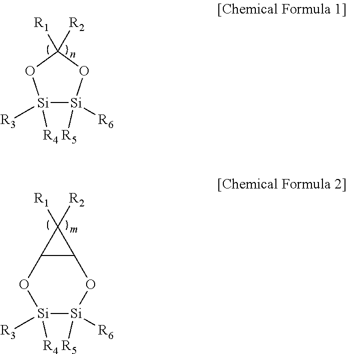

wherein
R₁ and R₂ may be identical to or different from each other, and are each independently a hydrogen atom, a linear, branched, or cyclic C₁-C₆ alkyl group, an allyl group containing a linear, branched, or cyclic C₁-C₆ functional group, a vinyl group containing a linear, branched, or cyclic C₁-C₆ functional group, an alkoxy group containing a linear, branched, or cyclic C₁-C₆ functional group, a primary or secondary amine group, or a phenyl group optionally containing a C₁-C₆ functional group,
R₃ to R₆ are ach independently a linear, branched, or cyclic C₁-C₆ alkyl group, an allyl group containing a linear, branched, or cyclic C₁-C₆ functional group, or a vinyl group containing a linear, branched, or cyclic C₁-C₆ functional group, n is 1 to 4, and m is 1 to 6.

Here, at least one of R₃ and R₆ may be a methyl group (Me), and R₃ to R₆ may all be identical.

In addition, the Chemical Formula 1 may be a silicon-containing compound represented by the following Chemical Formula 1-1:

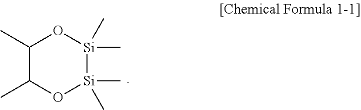

In addition, the Chemical Formula 2 may be a silicon-containing compound represented by the following Chemical Formula 2-1:

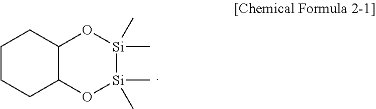

Furthermore, the precursor may additionally include a solvent. Here, the solvent may be one or more of saturated or unsaturated C₁-C₁₆ hydrocarbons, ketones, ethers, glymes, esters, tetrahydrofuran, and tertiary amines, and may be included in an amount of 1 to 99 wt % based on the total weight of the precursor for forming a low dielectric constant silicon-containing thin film.

The method for forming a low dielectric constant silicon-containing thin film according to the present disclosure is characterized by including a process of forming a thin film on a substrate using the precursor for forming a low dielectric constant silicon-containing thin film as described above.

Here, the process of forming a thin film on a substrate may include a process of forming a precursor thin film by depositing the precursor for forming a thin film on the surface of the substrate, and a process of reacting the precursor thin film with a reactive gas.

In addition, as the reactive gas, one or more of nitrogen (N₂), ammonia (NH₃), hydrazine (N₂H₄), nitrous oxide (N₂O), oxygen (O₂), water vapor (H₂O), ozone (O₃), hydrogen peroxide (H₂O₂), silane, hydrogen (H₂), and diborane (B₂H₆) may be used.

Furthermore, the process of forming a precursor thin film may include a process of vaporizing the precursor for forming the low dielectric constant silicon-containing thin film and transporting the vaporized precursor into a chamber.

In addition, the deposition may be performed by any one of a spin-on dielectric (SOD) process, a low-temperature plasma (LTP) process, a chemical vapor deposition (CVD) process, a plasma-enhanced chemical vapor deposition (PECVD) process, a high-density plasma chemical vapor deposition (HDPCVD) process, an atomic layer deposition (ALD) process, or a plasma-enhanced atomic layer deposition (PEALD) process.

In addition, the process of forming a thin film on a substrate may include a step of forming a thin film by supplying the precursor for forming a thin film to the substrate and applying plasma.

Moreover, the thin film may have a carbon content of 10 to 35 at % as measured by X-ray photoelectron spectroscopy (XPS), a refractive index (RI) of 1.3 to 1.7, an elastic modulus of 4 to 20 GPa, and a density of 1.2 to 1.7 g/cm³ as measured by X-ray reflectometry (XRR).

### Advantageous Effects

The precursor according to the present disclosure is capable of easily controlling a carbon content ratio within the molecule in a low dielectric constant silicon-containing thin film through a silicon-containing compound having a cyclic disilane structure and improving an elastic modulus of the formed thin film.

In addition, the precursor according to the present disclosure is a liquid at room temperature and thus easy to store and handle, and exhibits high reactivity, thereby achieving an excellent thin film growth rate.

In addition, the precursor for forming a low dielectric constant silicon-containing thin film has a structural characteristic that enables decomposition at a low temperature, thereby exhibiting suitability for low-temperature processes.

Furthermore, by using the precursor for forming a low dielectric constant silicon-containing thin film, it is possible to form a low dielectric constant silicon-containing thin film having a high elastic modulus, thereby providing a thin film formation method that can be utilized for applications such as next-generation DRAM IMD.

### DESCRIPTION OF DRAWINGS

FIG. 1 is a conceptual diagram showing a process in which the precursor comprising a silicon-containing compound represented by Chemical Formula 1-1 forms reaction sites by plasma application.

FIG. 2 shows the results of 1H-NMR analysis of the precursor according to Example 1.

FIG. 3 shows the results of 1H-NMR analysis of the precursor according to Example 2.

FIG. 4 shows the results of thermogravimetric analysis (TGA) of the precursors according to Examples.

### BEST MODE

Hereinafter, the present disclosure will now be described in more detail. The terms and expressions used in this specification and claims should not be interpreted in a limited or merely conventional or dictionary sense. Based on the principle that the inventors are entitled to appropriately define the concepts of terms in order to best describe the present disclosure, the terminology should be construed in accordance with the meaning and concepts consistent with the technical spirit of the present disclosure.

A precursor for forming a low dielectric constant silicon-containing thin film according to the present disclosure comprises a silicon-containing compound represented by the following Chemical Formula 1 or Chemical Formula 2, and a low dielectric constant silicon-containing thin film having a dielectric constant of 2.2 to 3.6 may be formed using the precursor for forming a low dielectric constant silicon-containing thin film.

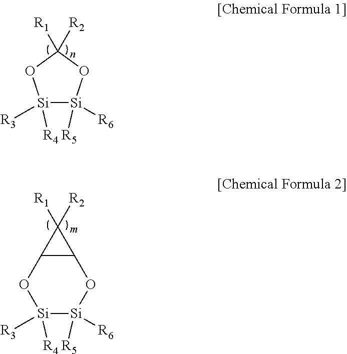

wherein R₁ and R₂ may be identical to or different from each other, and are each independently a hydrogen atom, a linear, branched, or cyclic C₁-C₆ alkyl group, an allyl group containing a linear, branched, or cyclic C₁-C₆ functional group, a vinyl group containing a linear, branched, or cyclic C₁-C₆ functional group, an alkoxy group containing a linear, branched, or cyclic C₁-C₆ functional group, a primary or secondary amine group, or a phenyl group optionally containing a C₁-C₆ functional group, R₃ to R₆ are ach independently a linear, branched, or cyclic C₁-C₆ alkyl group, an allyl group containing a linear, branched, or cyclic C₁-C₆ functional group, or a vinyl group containing a linear, branched, or cyclic C₁-C₆ functional group, n is 1 to 4, and m is 1 to 6.

Specific examples of the silicon-containing compounds represented by Chemical Formula 1 or Chemical Formula 2 include compounds having a chemical structure in which at least one of R₃ and R₆ is a methyl group (Me), and compounds in which R₃ to R₆ are all identical in chemical structure.

Preferably, the Chemical formula 1 may be a silicon-containing compound represented by the following Chemical Formula 1-1, and the Chemical Formula 2 may be a silicon-containing compound represented by the following Chemical Formula 2-1:

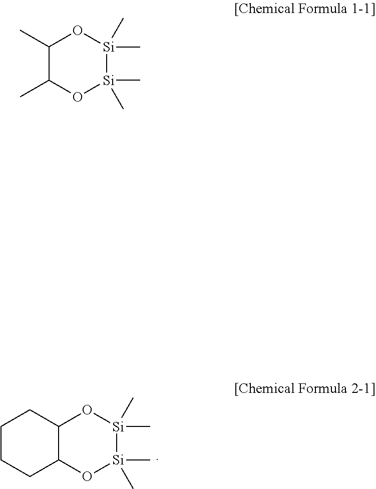

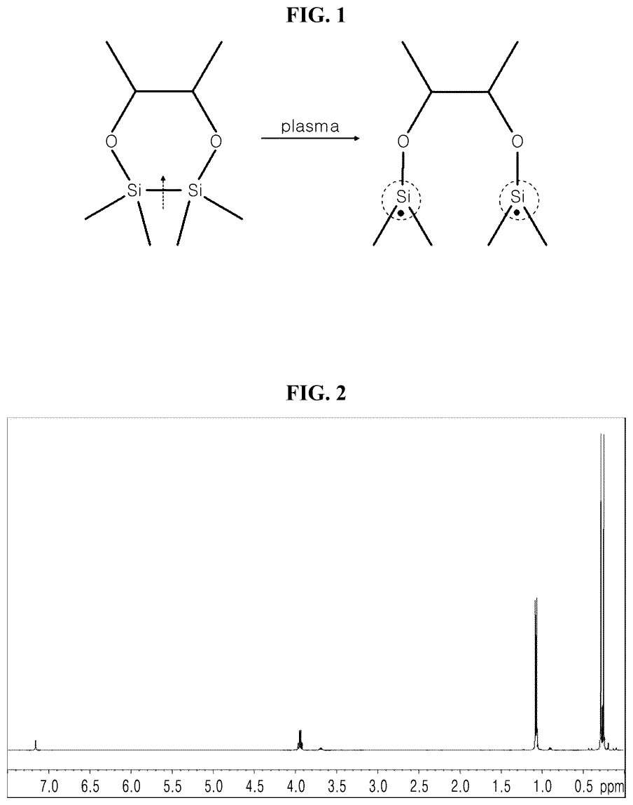

The silicon-containing compound represented by Chemical Formula 1 or Chemical Formula 2 includes a cyclic disilane structure. When energy such as plasma is applied after introducing the silicon-containing compound represented by Chemical Formula 1-1 onto a substrate, as shown in FIG. 1, the disilane (Si—Si) bond is broken up, thereby generating radicals on the silicon atoms and forming reaction sites. That is, since the Si—Si bond has relatively low bonding strength, it is easily cleaved by plasma application, and thin film deposition occurs on the surface through the reaction sites. Here, due to the characteristics of the chemical structure, an initial chemisorption rate on the surface of the thin film may be significantly enhanced. In addition, the tight bonding between the reaction sites and reactive groups on the surface of the thin film enables an improvement in the elastic modulus of the formed thin film.

Since R₃ in Chemical Formula 1 or Chemical Formula 2 is bonded to a silicon atom, it forms an Si—C bond within the thin film after being adsorbed onto the surface of the thin film. Such a surface adsorption process allows the dielectric constant of the formed thin film to be reduced.

In addition, the precursor of the present disclosure may additionally include a solvent. As the solvent, any one or a mixture of saturated or unsaturated C₁-C₁₆ hydrocarbons, ketones, ethers, glymes, esters, tetrahydrofuran, and tertiary amines may be used. Examples of the saturated or unsaturated C₁-C₁₆ hydrocarbons include toluene and heptane, and examples of the tertiary amine include dimethylethylamine.

In particular, when the silicon-containing compound forms a solid at room temperature or at a slightly elevated temperature, it is preferable to include a solvent capable of dissolving the compound. That is, when the solvent is included, it is contained in a type and amount capable of dissolving the silicon-containing compound, preferably in an amount of 1 to 99 wt % based on the total weight of the precursor for forming the silicon-containing thin film.

Since the precursor, with or without the above solvent, is vaporizable, it may be supplied into a chamber in the form of a precursor gas. Therefore, depending on the type of silicon-containing compound, if it exists as a liquid at room temperature and may be easily vaporized, a thin film formation process may be performed without a separate solvent.

That is, the method for forming a low dielectric constant silicon-containing thin film according to the present disclosure may include a process of forming a thin film on a substrate using a precursor for forming a low dielectric constant silicon-containing thin film.

Specifically, the process of forming a thin film on a substrate may include a process of forming a precursor thin film by depositing the precursor for forming a thin film on the surface of the substrate, and a process of reacting the precursor thin film with a reactive gas. Here, as the reactive gas, any one or more of nitrogen (N₂), ammonia (NH₃), hydrazine (N₂H₄), nitrous oxide (N₂O), oxygen (O₂), water vapor (H₂O), ozone (O₃), hydrogen peroxide (H₂O₂), silane, hydrogen (H₂), and diborane (B₂H₆) may be used.

In addition, the process may include a step of vaporizing the precursor for forming a low dielectric constant silicon-containing thin film and transferring the vaporized precursor into a chamber. The thin film may also be formed by supplying the precursor for forming the low dielectric constant silicon-containing thin film onto the substrate and applying plasma to deposit the precursor.

Specifically, the deposition process may be performed by any one of a spin-on dielectric (SOD) process, a low-temperature plasma (LTP) process, a chemical vapor deposition (CVD) process, a plasma-enhanced chemical vapor deposition (PECVD) process, a high-density plasma chemical vapor deposition (HDPCVD) process, an atomic layer deposition (ALD) process, or a plasma-enhanced atomic layer deposition (PEALD) process.

For example, when the HDP-CVD process is applied, it may be performed under high-vacuum and high-power conditions compared to an atmospheric pressure chemical vapor deposition (AP-CVD) process, a low-pressure chemical vapor deposition (LP-CVD) process, or a plasma-enhanced chemical vapor deposition (PE-CVD) process, thereby enabling the formation of a structurally dense thin film having excellent mechanical properties.

In addition, when plasma is applied, the plasma may be applied while the precursor for forming the low dielectric constant silicon-containing thin film that has been transferred into the chamber and another source gas are supplied onto the substrate.

For example, by supplying the precursor for forming a low dielectric constant silicon-containing thin film in the form of a gas, oxygen gas, and hydrogen gas as a carrier gas onto a substrate having a metal wiring pattern formed thereon, and generating plasma therein, a low dielectric constant interlayer insulating film that fills the gaps between the metal wiring patterns formed on the substrate may be formed. Further, in order to form a fluorinated silicon-containing insulating film, a fluorine source gas may also be supplied together to form the thin film.

In addition, depending on the type of the interlayer insulating film, a low dielectric constant insulating film that fills the gaps between the metal wiring patterns on the substrate may be formed by supplying a silicon source gas, a fluorine source gas, an oxygen gas, and a carbon-containing gas together with an inert gas such as argon (Ar) or helium (He) gas, onto the substrate and generating plasma.

As the fluorine source, SiF₄, which is commonly used, may be used, and as the carbon-containing gas, a hydrocarbon gas such as CH₄, C₂H₄, C₂H₆, C₂H₂, or C₆H₆, or an organosiloxane source gas such as methyltriethoxysilane (MTES), diethoxymethylsilane (DEMS), dimethoxymethylsilane (DMOMS), tetramethylcyclotetrasiloxane (TOMCATS), dimethyldimethoxysilane (DMDMOS), dimethyldioxysilylcyclohexane (DMDOSH), or trimethylsilane may be used.

The process for forming the thin film may be performed under chamber pressure conditions of 0.1 to 10 Torr. In addition, the source power for forming plasma within the chamber is preferably 50 to 9,000 W, and the bias power is preferably 0 to 5,000 W. Furthermore, the bias power may not be applied in certain cases.

Due to the structural characteristics of the silicon-containing compound used in the present disclosure during the thin film formation process, micropores are formed when the interlayer insulating film is formed. The formation of these pores further reduces the dielectric constant of the interlayer insulating film, thereby achieving a lower dielectric constant compared to conventional interlayer insulating films.

In addition, since the bonding strength between the silicon-containing compound and the surface of thin film is enhanced, the mechanical properties of the formed thin film are enhanced.

Furthermore, by applying the thin film formation process, a semiconductor device including a low dielectric constant silicon-containing thin film may be manufactured. Here, the low dielectric constant silicon-containing thin film forms a fluorinated silicate glass (FSG) film or an organosilicate glass (OSG) film as an interlayer insulating film, thereby reducing parasitic capacitance between the wirings of the semiconductor device and enabling the formation of a high-quality semiconductor device.

Thus, the thin film obtained by applying the thin film formation method according the present disclosure exhibits excellent properties. For example, the thin film may have a carbon content of 10 to 35 at % as measured by X-ray photoelectron spectroscopy (XPS). In addition, the thin film may have a refractive index (RI) of 1.3 to 1.7. In addition, the thin film may have an elastic modulus of 4 to 20 GPa. Furthermore, the thin film may have a density of 1.2 to 1.7 g/cm³ as measured by X-ray reflectometry (XRR). Furthermore, the thin film may be formed as a low-dielectric thin film having a dielectric constant of 2.2 to 3.6.

Accordingly, since a low-dielectric thin film having a high elastic modulus may be obtained due to these thin film characteristics, it may be utilized in semiconductor devices such ss next-generation DRAM IMD.

The effects of the present disclosure will be described in the following Examples.

### Example 1. Preparation of 2,2,3,3,5,6-Hexamethyl-1,4,2,3-dioxadisilinane

A solution was prepared by diluting 43 mL (0.3 mol) of triethylamine with 600 mL of hexane. To this solution, a solution of 25 g (0.13 mol) of 1,2-dichlorotetramethyldisilane and 12 g (0.13 mol) of 2,3-butanediol diluted in 100 mL of hexane was slowly added at a low temperature (about 0° C.) to prepare a mixture. Then, the mixture was stirred at room temperature for about 12 hours. The reaction mixture was filtered, and the filtrate was heated under atmospheric pressure to remove residual triethylamine and hexane, yielding a colorless liquid.

The obtained liquid was purified under reduced pressure [80° C. (bath standard) @ 4 torr] to afford 18.2 g of 2,2,3,3,5,6-hexamethyl-1,4,2,3-dioxadisilinane (yield: 65%) as a colorless liquid.

The obtained product was measured by ¹H-NMR (400 MHz, C₆D₆, 25° C.), and as shown in FIG. 2, characteristic peaks were observed at 0.25 [s, 6H, meso-Si(CH₃)₂], 0.26 [s, 0.9H, dl-Si(CH₃)₂], 00.28 [s, 6.9H, meso and dl-Si(CH₃)₂], 1.06 [d, J=6.1 Hz, 0.8H, dl-CH (CH₃)], 1.07 [d, J=6.6 Hz, 6H, meso-CH(CH₃)], 3.69 [m, 0.2H, dl-CH(CH₃)], and 3.94 [q, J=6.6 Hz, 2.0 H, meso-CH(CH₃)], confirming the chemical structure.

### Example 2. Preparation of 2,2,3,3-tetramethyloctahydrobenzo-1,4,2,3-dioxadisiline

A solution was prepared by diluting 8.5 mL (0.02 mol) of triethylamine with 300 mL of hexane. To this solution, a solution of 25 g (0.13 mol) of 1,2-dichlorotetramethyldisilane and 3.1 g (0.02 mol) of 1,2-cyclohexanediol diluted in 50 mL of tetrahydrofuran was slowly added at a low temperature (about 0° C.). Then, the mixture was stirred at room temperature for about 12 hours. The reaction mixture was filtered, and the filtrate was heated under atmospheric pressure to remove residual triethylamine, hexane, and tetrahydrofuran, yielding a colorless liquid.

The obtained liquid was purified under reduced pressure [60° C. (bath standard) @0.8 torr] to afford 3.7 g of 2,2,3,3-tetramethyloctahydrobenzo-1,4,2,3-dioxadisiline (yield: 3.7 g, 60%) as a colorless liquid.

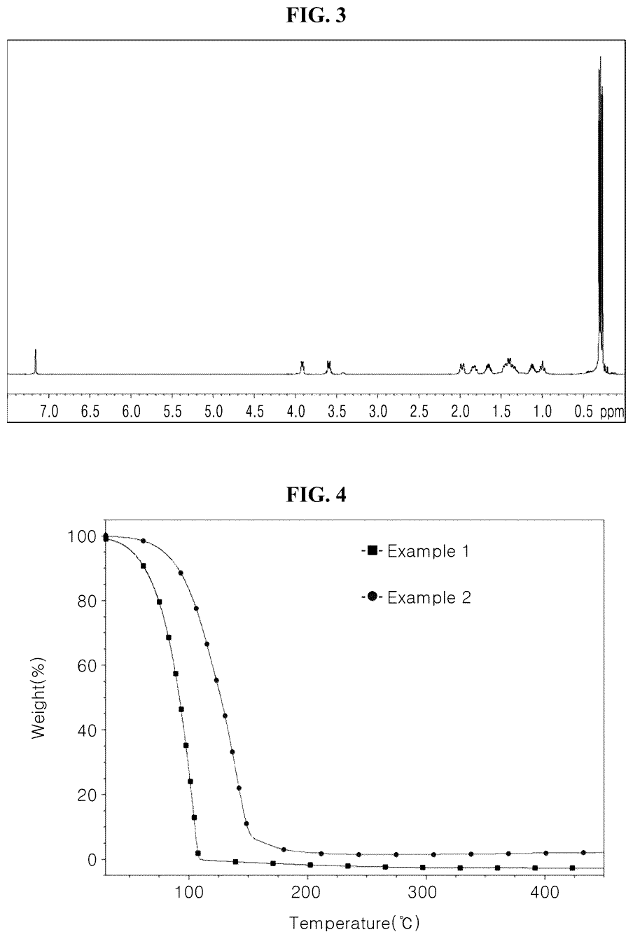

The obtained product was measured by 1H-NMR (400 MHz, C₆D₆, 25° C.), and as shown in FIG. 3, characteristic peaks were observe at δ 0.26-0.31 [m, 12H, —Si(CH₃)₂], 0.99 [m, 1H, cycle-(CHCH₂—CH₂)—], 1.12 [m, 1H, cycle-(CHCH₂—CH₂)—], 1.28-1.49 [m, 3H, cycle-(CHCH₂—CH₂)—], 1.65 [m, 1H, cycle-(CHCH₂—CH₂)—], 1.83 [m, 1H, cycle-(CHCH₂—CH₂)—], 1.97 [m, 1H, cycle-(CHCH₂—CH₂)—], 3.59 [m, 1H, cycle-(CHCH₂—CH₂)—], and 3.91 [m, 1H, cycle-(CHCH₂—CH₂)—], confirming the chemical structure.

In addition, as shown in the thermogravimetric analysis results of FIG. 4, it was found that the compounds of Examples 1 and 2 exhibited weight changes in the temperature range of 100 to 150° C., which may provide a beneficial effect on the deposition process.

Therefore, the precursor comprising the silicon-containing compound according to the present disclosure is considered to exhibit properties suitable for use in a process for forming a low dielectric constant silicon-containing thin film.

### Process Example

An SiCOH thin film was formed through the thin film formation process of the present disclosure. That is, a carbon-containing silicon oxide thin film was formed by simultaneously injecting a silicon precursor, oxygen, and helium using a 6″ ATOMIC PREMIUM manufactured by CN1 Co., Ltd.

For stable injection of the silicon precursor during the process, the precursor was supplied to the reactor using helium (He) gas as a carrier gas in a precursor storage canister, and oxygen was used as a reactant to deposit a carbon-containing silicon oxide thin film by a plasma-enhanced chemical vapor deposition method. Here, the substrate was heated to 300° C., and plasma was generated by applying RF power of 100 to 300 W at a frequency of 13.56 MHz. The reactor pressure was maintained at 2 Torr.

The thin films were deposited by varying process conditions such as plasma application conditions, reactive gas, and carrier flow rates. For each deposited thin film, the dielectric constant, density, and carbon content were measured.

The refractive index (RI) of deposited thin films was analyzed by ellipsometry in the range of 1.3 to 5.0 eV, and the refractive index at 1.96 eV is shown in Table 1. The element composition ratio in the thin film, including carbon content, was measured by X-ray photoelectron spectroscopy (XPS), and the density was measured by X-ray reflectivity (XRR). The dielectric constant was measured by contacting the deposited thin film with an Hg-probe, with the AC frequency set to 250 Hz. The elastic modulus was measured using a nanoindenter at a depth corresponding to 20% of the film thickness from the surface of the deposited thin film.

The deposition conditions and measurement results for each thin film are shown in Table 1 below.

TABLE 1

| | | | | | Measured values | | | | |
|---|---|---|---|---|---|---|---|---|---|
| | Deposition conditions | | | | | | | XPS | |
| | RF | He | O₂ | Electrode | | | Elastic | carbon | XRR |
| | power | flow rate | flow rate | spacing | | Dielectric | modulus | content | density |
| Sample | [W] | [sccm] | [sccm] | [mm] | RI | constant | [GPa] | [at %] | [g/cm³] |
| 1 | 200 | 300 | 10 | 40 | 1.44 | 2.61 | 6.92 | 24.94 | 1.35 |
| 2 | 200 | 300 | 5 | 40 | 1.46 | 2.69 | 8.83 | 27.80 | 1.33 |
| 3 | 200 | 300 | 2 | 40 | 1.49 | 2.70 | 10.25 | 31.93 | 1.36 |
| 4 | 200 | 300 | 2 | 30 | 1.53 | 2.71 | 14.64 | 31.15 | 1.42 |
| 5 | 200 | 300 | 10 | 30 | 1.44 | 2.87 | 11.38 | 19.91 | 1.44 |
| 6 | 200 | 300 | 5 | 20 | 1.50 | 2.95 | 14.88 | 27.54 | 1.48 |
| 7 | 100 | 300 | 10 | 20 | 1.45 | 2.99 | 12.30 | 19.93 | 1.46 |
| 8 | 200 | 300 | 40 | 20 | 1.44 | 2.99 | 13.70 | 13.94 | 1.52 |
| 9 | 200 | 300 | 40 | 30 | 1.41 | 2.99 | 13.60 | 11.06 | 1.54 |
| 10 | 200 | 300 | 40 | 25 | 1.42 | 3.00 | 13.22 | 13.41 | 1.51 |

The results of Table 1 indicate that the manufactured thin films may be used as low-dielectric materials for reducing RC delay in semiconductor devices. Low-dielectric materials in the semiconductor device field are evaluated by their dielectric constant and elastic modulus, etc. Thin films with a low dielectric constant and a high elastic modulus are considered superior in the art. The dielectric constant may be lowered by introducing carbon-containing functional groups into a silicon oxide-based material; however, this tends to lower the elastic modulus as well. That is, the dielectric constant and elastic modulus exhibit a trade-off relationship. The thin film obtained by applying the thin film formation method according to the present disclosure was evaluated to be a high-quality thin film that satisfies all of these various physical properties.

While the present disclosure has been described with reference to preferred embodiments as described above, it is not limited to these embodiments, and various modifications and variations can be made by those skilled in the art without departing from the spirit of the present disclosure. Such modifications and variations should be considered to fall within the scope of the present disclosure and the appended claims.

1. A precursor for forming a low dielectric constant silicon-containing thin film, comprising a silicon-containing compound represented the following Chemical Formula 1 or Chemical Formula 2,
characterized in that the precursor for forming a low dielectric constant silicon-containing thin film forms a low dielectric constant silicon-containing thin film having a dielectric constant of 2.2 to 3.6: 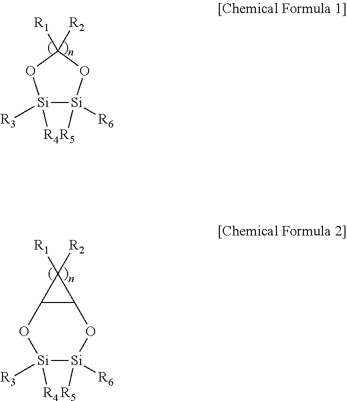
wherein R₁ and R₂ may be identical to or different from each other, and are each independently a hydrogen atom, a linear, branched, or cyclic C₁-C₆ alkyl group, an allyl group containing a linear, branched, or cyclic C₁-C₆ functional group, a vinyl group containing a linear, branched, or cyclic C₁-C₆ functional group, an alkoxy group containing a linear, branched, or cyclic C₁-C₆ functional group, a primary or secondary amine group, or a phenyl group optionally containing a C₁-C₆ functional group,
R₃ to R₆ are ach independently a linear, branched, or cyclic C₁-C₆ alkyl group, an allyl group containing a linear, branched, or cyclic C₁-C₆ functional group, or a vinyl group containing a linear, branched, or cyclic C₁-C₆ functional group, n is 1 to 4, and m is 1 to 6.

2. The precursor for forming a low dielectric constant silicon-containing thin film of claim 1, characterized in that at least one of R₃ and R₆ is a methyl group (Me).

3. The precursor for forming a low dielectric constant silicon-containing thin film of claim 1, characterized in that R₃ to R₆ are all identical.

4. The precursor for forming a low dielectric constant silicon-containing thin film of claim 1, characterized in that Chemical Formula 1 is a silicon-containing compound represented by the following Chemical Formula 1-1:

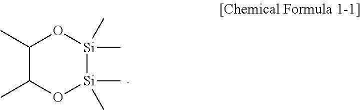

5. The precursor for forming a low dielectric constant silicon-containing thin film of claim 1, characterized in that Chemical Formula 2 is a silicon-containing compound represented by the following Chemical Formula 2-1:

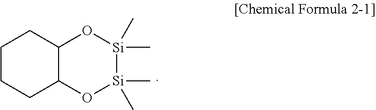

6. The precursor for forming a low dielectric constant silicon-containing thin film of claim 1, characterized in that further comprising a solvent.

7. The precursor for forming a low dielectric constant silicon-containing thin film of claim 6, characterized in that the solvent is one or more of saturated or unsaturated C₁-C₁₆ hydrocarbons, ketones, ethers, glymes, esters, tetrahydrofuran, and tertiary amines.

8. The precursor for forming a low dielectric constant silicon-containing thin film of claim 6, characterized in that the solvent is included in an amount of 1 to 99 wt % based on the total weight of the precursor for forming a low dielectric constant silicon-containing thin film.

9. A method for forming a low dielectric constant silicon-containing thin film, comprising a process of forming a thin film on a substrate using the precursor for forming a low dielectric constant silicon-containing thin film of according to claim 1, characterized in that the low dielectric constant silicon-containing thin film has a dielectric constant of 2.2 to 3.6.

10. The method for forming a low dielectric constant silicon-containing thin film of claim 9, characterized in that the process of forming a thin film on a substrate includes:
a process of forming a precursor thin film by depositing the precursor for forming a thin film on the surface of the substrate; and
a process of reacting the precursor thin film with a reactive gas.

11. The method for forming a low dielectric constant silicon-containing thin film of claim 10, characterized in that reactive gas is any one or more of nitrogen (N₂), ammonia (NH₃), hydrazine (N₂H₄), nitrous oxide (N₂O), oxygen (O₂), water vapor (H₂O), ozone (O₃), hydrogen peroxide (H₂O₂), silane, hydrogen (H₂), and diborane (B₂H₆).

12. The method for forming a low dielectric constant silicon-containing thin film of claim 9, characterized in that the process of forming a precursor thin film includes a process of vaporizing the precursor for forming a low dielectric constant silicon-containing thin film and transferring the vaporized precursor into a chamber.

13. The method for forming a low dielectric constant silicon-containing thin film of claim 10, characterized in that the deposition is performed by any one of a spin-on dielectric (SOD) process, a low-temperature plasma (LTP) process, a chemical vapor deposition (CVD) process, a plasma-enhanced chemical vapor deposition (PECVD) process, a high-density plasma chemical vapor deposition (HDPCVD) process, an atomic layer deposition (ALD) process, or a plasma-enhanced atomic layer deposition (PEALD) process.

14. The method for forming a low dielectric constant silicon-containing thin film of claim 9, characterized in that the process of forming a thin film on a substrate includes a step of forming a thin film by supplying the precursor for forming a low dielectric constant silicon-containing thin film to the substrate and applying plasma.

15. The method for forming a low dielectric constant silicon-containing thin film of claim 9, characterized in that the thin film has a carbon content of 10 to 35 at % as measured by X-ray photoelectron spectroscopy (XPS).

16. The method for forming a low dielectric constant silicon-containing thin film of claim 9, characterized in that the thin film has a refractive index (RI) of 1.3 to 1.7.

17. The method for forming a low dielectric constant silicon-containing thin film of claim 9, characterized in that the thin film has an elastic modulus of 4 to 20 GPa.

18. The method for forming a low dielectric constant silicon-containing thin film of claim 9, characterized in that the thin film has a density of 1.2 to 1.7 g/cm³ as measured by X-ray reflectometry (XRR).
